(19) United States
(12) Patent Application Publication
(10) Pub. No.: US 2006/0077741 A1
(43) Pub. Date: Apr. 13, 2006

(54) Multilevel phase-change memory, manufacturing and status transferring method thereof

(76) Inventors: Wen-Han Wang, Hsinchu (TW); Chien-Ming Li, Hsinchu (TW); Kuei-Hung Shen, Hsinchu (TW)

Correspondence Address: HARNESS, DICKEY & PIERCE, P.L.C., P.O. BOX 8910, RESTON, VA, 20195, US

(21) Appl. No.: 11/182,866

(22) Filed: Jul. 18, 2005

(30) Foreign Application Priority Data
Oct. 8, 2004 (TW) 93130598

(51) Int. Cl. G11C 7/00

(52) U.S. Cl. 365/222

(57) ABSTRACT

A multilevel phase-change memory, manufacturing method and status transferring method thereof. The phase-change memory includes two phase-change layers and electrodes, which are configured in a series structure to form a memory cell. A current-drive mode is employed to control and drive the memory such that multilevel memory states may be achieved by imposing different current levels. The provided multilevel phase-change memory has more bits and higher capacity than that of the memory with a single phase-change layer. Furthermore, the series structure may reduce the cell area and the device volume.

This application claims the benefit of Taiwan Patent Application No. 93130598, filed on Oct. 8, 2004, which is hereby incorporated by reference for all purposes as if fully set forth herein.

### BACKGROUND OF THE INVENTION

1. Field of Invention

The invention relates to a semiconductor memory device, and more particularly to a semiconductor memory device with a multi-level memory state.

2. Related Art

Memory is widely used in most electronic devices. Most are DRAM, SRAM, or Flash memory. Application and architecture of electric devices determines the usage of the memory and the required capacity. Development of memory technology, such as FeRAM, MRAM and phase change memory, is on-going.

Phase change semiconductor memory stores data through resistance variation caused by the phase change of materials. Regarding the phase materials, in the 1960s, S. R. Ovshinsky of the U.S. company ECD discovered that crystallization and amorphization of chalcogenide has a distinct difference in optical reflectance and electrical conductivity. It is capable of fast reversible transformation and has switching/memory application.

Phase change memory is called a semiconductor memory because chalcogenide belongs to the VIA group in the Periodic Table Of Elements, and is a semiconductive material between metals and nonmetals. Adding some elements is required for specific purposes in practical use, e.g., increasing amorphization/crystallization speed, or crystallization characteristics.

Phase change memory meets the need for large and fast storage operation and long storage time. It has the advantages of small volume, more storage data, and fast operation speed and it can store data for more than ten years under 130° C. Therefore, phase change memory is a non-volatile memory with great potential, having high read/write speed, high density, long endurance, low power consumption, and radiation resistance. Main technology trends focus on higher record density and low power consumption through reducing memory cell size.

However, multi-level/multi-state memory is another consideration to increase memory density besides reducing the cell size. Thus, a single memory cell may have more than two memory states without changing the component size.

In the related art, Tyler Lowrey (Ovonyx Inc.) provides a multi-state structure in a published company technology document. A memory cell with a single phase change layer is employed to obtain multi levels with different resistance values by controlling the reset current. However, the solution may have the problem of small current separation such that writing error occurs due to the current offset. Besides, the multi-state is difficult to control after continuous operations due to the heating effects.

U.S. Pat. No. 5,534,711 discloses a multi level storage device to improve the stability for multilevel operations.

U.S. Pat. No. 6,507,061 discloses a phase change memory having two phase change layers separated by a barrier layer, which may reduce the programmed volume and provide a suitable heat sink. One of the phase change layers is not employed to store data but to maintain the temperature.

Also, U.S. Pat. No. 6,635,914 discloses a four level memory cell that belongs to the category of Programmable Metallization Cell Memory (PMCm). The cell is composed of a solid electrolyte layer and two electrodes. The conductivity of the solid electrolyte layer is changed by delivering an electrical field by the electrodes.

Phase change memory, MRAM, and FRAM are the main memory technology trends which have the advantages of being non-volatility, high speed (close to the operation speed of DRAM and SRAM), large capacity, high density, high environment endurance, and long storage time. Furthermore, operation voltage decreases gradually. These memories may substitute Flash memory in the near future. Therefore, there is an urgent need for a new phase change memory structure.

### SUMMARY OF THE INVENTION

Accordingly, the invention relates to a multilevel phase-change memory, its manufacturing method and its operating method, which substantially solves the problems of the related art.

An object of the invention is to provide a multilevel phase-change memory, its manufacturing method and its operating method, having four memory states through one single memory cell.

The other object of the invention is to provide a multilevel phase-change memory, its manufacturing method and its operating method, in which the memory cell is configured by two independent phase change units formed in series in order to obtain a memory cell with high density. The materials of the phase change units may be the same or different.

Additional features and advantages of the invention will be set forth in the following description, and in part will be apparent from the description, or may be learned by practice of the invention. The objectives and other advantages of the invention will be realized and attained by the structure particularly pointed out in the written description and claims hereof as well as the appended drawings.

To achieve these and other advantages and in accordance with the purpose of the invention, a phase change memory includes a first phase change layer and a second phase change layer. The first phase change layer has a first characteristic curve of a current-time relationship, which includes a crystallization state and an amorphous state, while the second phase change layer has a second characteristic curve of a current-time relationship, which includes a crystallization state and an amorphous state. The first and second characteristic curves cross with each other to form a first state, a second state, a third state, and a fourth state. The first phase change layer and the second phase change layer are at a crystallization state in the first state, while the first phase change layer is at an amorphous state and the second phase change layer is at a crystallization state in the second state. The first phase change layer is at a crystallization state and the second phase change layer is at an amorphous state in the third state, while the first phase change layer and the second phase change layer are at an amorphous state in the fourth state.

To achieve these and other advantages and in accordance with the purpose of the invention, a phase change memory includes a first phase change layer; a second phase change layer; an intermediate layer formed between the first phase change layer and the second phase change layer; a first electrode formed on another side of the first phase change layer; and a second electrode formed on another side of the second phase change layer.

To achieve these and other advantages and in accordance with the purpose of the invention, a state transformation method for a phase change memory includes the steps of imposing a first pulse to make the first phase change layer and the second change layer crystallize; and imposing a second pulse to change the crystallization state of the first phase change layer and the second change layer. The first pulse and the second pulse are voltage signals. The third pulse and the fourth pulse are voltage signals.

To achieve these and other advantages and in accordance with the purpose of the invention, a state transformation method for a phase change memory includes the steps of imposing a pulse to change the crystallization state of the first phase change layer and the second change layer. The pulse is a voltage signal.

According to the object of the invention, the phase change memory has the advantage of reducing the area of one bit. Thus, the memory density is increased.

According to the object of the invention, the phase change memory has the advantage of direct writing and erasing operations.

According to the object of the invention, the phase change memory has the advantage of shortening time for writing and erasing operations.

According to the object of the invention, the phase change memory has the advantage of reducing complexity for fabricating the devices. Additional masks are not necessary for the process of the memory.

According to the object of the invention, the phase change memory employ series configuration and may adopt the same process for the single phase change layer.

According to the object of the invention, the phase change memory has two bits in one single cell under the same area. The memory has the advantage of increasing the density of the device.

Further scope of applicability of the invention will become apparent from the detailed description given hereinafter. However, it should be understood that the detailed description and specific examples, while indicating embodiments of the invention, are given by way of illustration only and are intended to provide further explanation of the invention as claimed, since various changes and modifications within the spirit and scope of the invention will become apparent to those skilled in the art from this detailed description.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIG. 1 is a structure diagram of the phase change memory according to the invention;

FIG. 2 is another structure diagram of the phase change memory according to the invention;

FIG. 3A˜FIG. 3E illustrate the fabricating process of the phase change memory according to the invention;

FIG. 4A˜FIG. 4D are the illustrative diagrams of the four memory states of the phase change memory according to the invention;

FIG. 5A˜FIG. 5D are the experimental diagrams of the four memory states of the phase change memory according to the invention;

FIG. 6 illustrates the operation method for memory state transferring of the phase change memory according to the invention; and

FIG. 7 illustrates the operation method for memory state transferring of the phase change memory according to the invention.

### DETAILED DESCRIPTION OF THE INVENTION

Reference will now be made in detail to an embodiment of the invention, examples of which are illustrated in the accompanying drawings. Reference in the specification to “one embodiment” or “an embodiment” means that a particular feature, structure, or characteristic described in connection with the embodiment is included in at least one embodiment of the invention. The phrase “in one embodiment” in various places in the specification does not necessarily refer to the same embodiment.

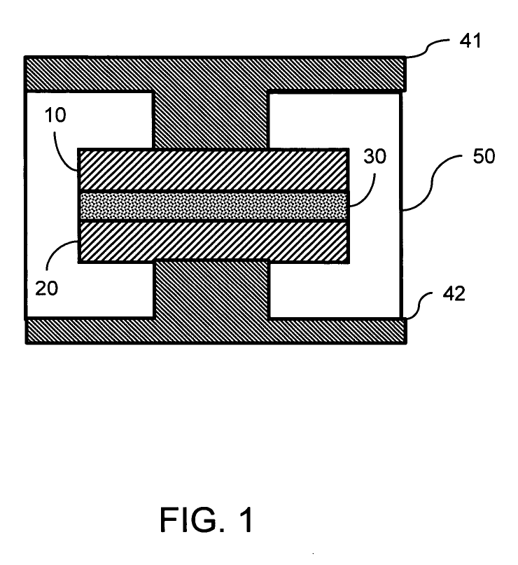

Refer to FIG. 1, which illustrates the structure of the phase change memory of the invention. In the embodiment, the phase change memory includes a first phase change layer 10, a second phase change layer 20, an intermediate layer 30, a first electrode 41 and a second electrode 42. The first phase change layer 10 and the second phase change layer 20 are formed on two surfaces of the intermediate layer 30 by a semiconductor process. The first electrode 41 is formed on another side of the first phase change layer 10 by a semiconductor process. The second electrode 42 is formed on another side of the second phase change layer 20 by a semiconductor process.

In another embodiment, a protection layer 50 is formed from dielectric material by a semiconductor process to cover and protect the first phase change layer 10, the second phase change layer 20, the intermediate layer 30, the first electrode 41 and the second electrode 42. The first electrode 41 and the second electrode 42 deliver voltage or current signals such that the first phase change 10 layer and the second phase change 20 layer are heated to change the state through the electrical signals, thereby controlling the operation of the phase change memory in accordance with the invention.

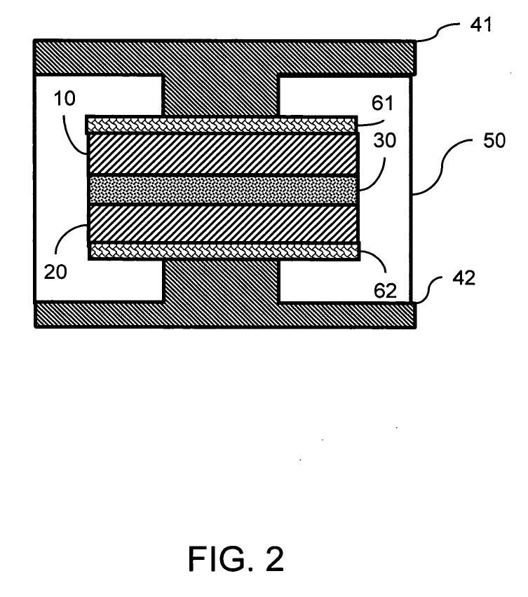

Refer to FIG. 2, in which the main structure of the phase change memory is the same as that in the embodiment of FIG. 1. A first functional layer 61 and a second functional layer 62 are optionally formed between the first electrode 41 and the first phase change layer 10, and between are the second electrode 42 and the second phase change layer 20. The materials of the first functional layer 61 and the second functional layer 62 may be poly-Si, or SiC. In one embodiment, the first functional layer 61 and the second functional layer 62 may be a heating layer for increasing heating efficiency. In one embodiment, the first functional layer 61 and the second functional layer 62 may be a nucleation accelerating layer for accelerating the crystallization speed of the first phase change layer. In another embodiment, the first functional layer 61 and the second functional layer 62 may be a diffusion stop layer for preventing diffusion between the first phase change layer and the first electrode. The first functional layer 61 and the second functional layer 62 may have one, two or all functions listed above according to the characteristics of the materials.

The area of the first functional layer 61 may be the same as or different from that of the electrode, and the same as or different from that of the phase change layer. Similarly, the area of the second functional layer 62 may be the same as or different from that of the electrode, and the same as or different from that of the phase change layer. The first functional layer 61 and the second functional layer 62 may be the same or different. The embodiment illustrated in the figure is only exemplary and descriptive, and is not intended to limit the area and thickness of the first functional layer 61 and the second functional layer 62. In one embodiment, either the first functional layer 61 or the second functional layer 62 is optionally arranged.

According to the principle of the invention, two phase change layers are employed and connected in series to form one single memory cell. Each phase change layer has a crystallization state and an amorphous state, which may be changed by heating.

The first phase change layer 10 has a crystallization state and an amorphous state, while the second phase change layer 20 has a crystallization state and an amorphous state. Thus four states are formed when the two phase change layers are connected in series. The four states are referred as the first state, second state, third state and fourth state hereinafter. The conditions for the four states will be described in the following.

The first phase change layer 10 has a first characteristic curve of a current-time relationship, which includes a crystallization state and an amorphous state, while the second phase change layer 20 has a second characteristic curve of a current-time relationship, which includes a crystallization state and an amorphous state. The first phase change layer 10 and the second phase change layer 20 are configured in series. The first and second characteristic curves cross with each other to form a first state, a second state, a third state, and a fourth state. The first phase change layer 10 and the second phase change layer 20 are at a crystallization state in the first state, while the first phase change layer 10 is at an amorphous state and the second phase change layer 20 is at a crystallization state in the second state. The first phase change layer 10 is at a crystallization state and the second phase change layer 20 is at an amorphous state in the third state, while the first phase change layer 10 and the second phase change layer 20 are at an amorphous state in the fourth state.

The first phase change layer 10 and the second phase change layer 20 are different materials for phase change, which have distinct characteristics and preferably resistant differences. The characteristics of the two materials are contrary. Also, the crystallization and amorphization speed of the first phase change layer 10 and the second phase change layer 20 are preferably different. For example, one of the two layers may employ a material with the characteristics of low resistance, high crystallization temperature and fast crystallization speed, while the other may employ a material with the characteristics of high resistance, low crystallization temperature and slower crystallization speed. In one embodiment, the materials of the first phase change layer 10 and the second phase change layer 20 are different. In another embodiment, the two layers may adopt the same phase change material. The technological effect of the four memory states may be achieved by forming the two single phase change cells in series through optimized structural design.

For example, the first phase change layer 10 may employ doped eutectic SbTe, AgInSbTe or GeInSbTe. The second phase change layer 20 may employ GeSbTe compounds, such as Ge2Sb2Te5. The aforementioned materials are for illustration only, and are not intended to limit the composition of the invention. Two phase change layers with different resistant variations and crystallization/amorphization speeds may be obtained by changing the ingredients of the phase change layers, adjusting the thickness of the phase change layers, differentiating the top electrodes types and contact areas, or forming functional layers between the phase change layers and the top electrodes.

The intermediate layer 30 may adopt materials having stable structure with good electrical and heating conductivity. For example, the material may be metal nitride, metal carbide, or metal silicide.

The materials of the first electrode 41 and the second electrode 42 may be the same or different. In one embodiment, for simplifying the fabricating process, the materials of the first electrode 41 and the second electrode 42 may be the same. The heating efficiency is controlled by adjusting the sizes of the electrodes. In one embodiment, the size of the first electrode 41 and the second electrode 42 may be the same. In another embodiment, the size of the first electrode 41 and the second electrode 42 may be different. The size of the electrodes is adjusted to control the heating efficiency.

In one embodiment, the provided phase change memory selects the cell to be written in or read out through transistors, which may be, for example, MOSFET, or BJT. Sufficient heat for phase change of the first phase change layer 10 and the second phase change layer 20 is generated by imposing voltages on the heater, or the first electrode 41 and the second electrode 42. Then the signals are delivered to the receiving ends and sensing amplifier through the electrodes. According to the principle of the invention, the operation of the multilevel phase change memory is controlled by imposing currents and time.

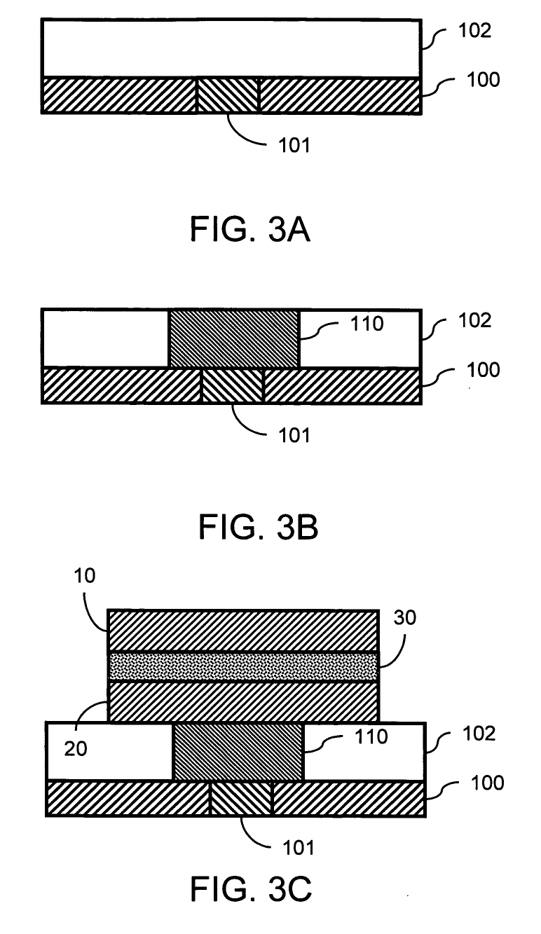

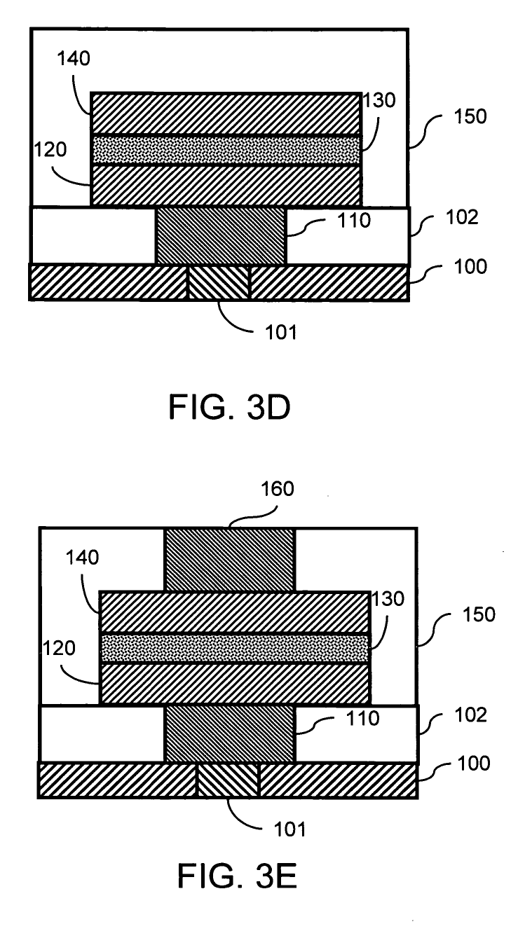

Refer to FIG. 3A˜3I illustrating the fabricating process of the phase change memory according to the invention.

A substrate 100, in which a metal contact 101 is formed, is provided in the former manufacturing process for CMOS or bipolar. Then an oxide layer 102 is deposited on the substrate 100 as illustrated in FIG. 3A.

A through hole is formed by masking and etching processes. A first electrode 110 is formed in the through hole, as illustrated in FIG. 3B. Then, a first phase change layer 120, an intermediate layer 130, and a second phase change layer 140 are formed sequentially, as illustrated in FIG. 3C.

Then an oxide layer 150 is formed, as illustrated in FIG. 3D. Another through hole is formed by masking and etching processes. A second electrode 160 is formed in the through hole, as illustrated in FIG. 3E.

As described in the above mentioned embodiments, a first functional layer is further formed between the first electrode 110 and the first phase change layer 120, while a second functional layer is further formed between the second electrode 150 and the second phase change layer 140.

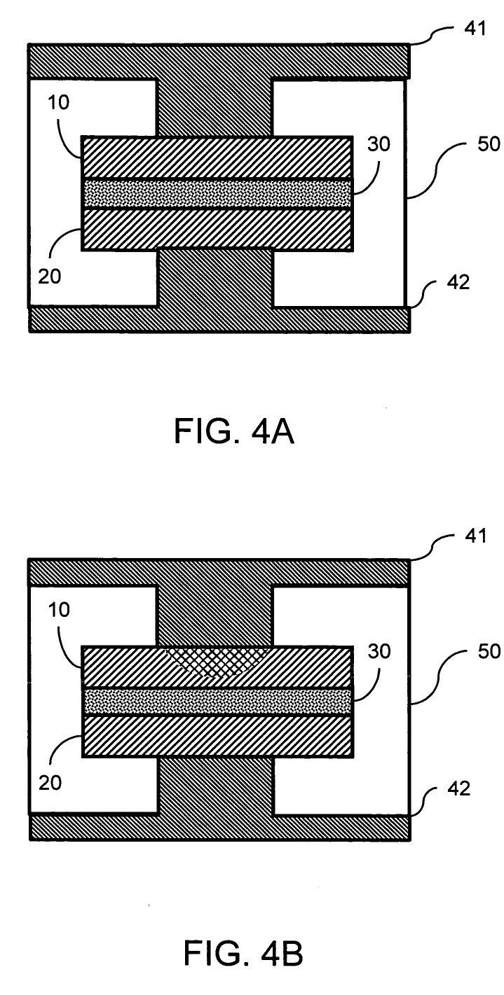

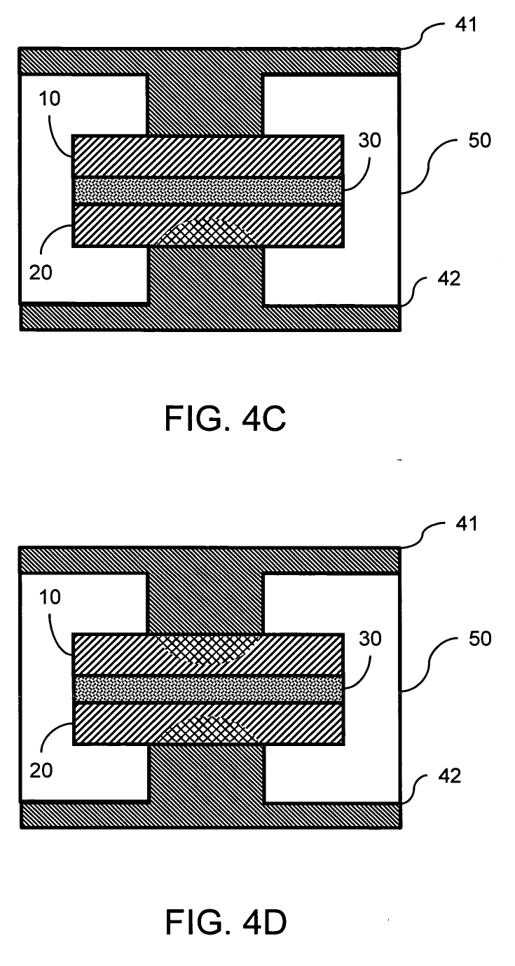

The operation of the phase change memory in accordance with the invention is illustrated as follows. Refer to FIG. 4A and FIG. 4D.

The phase change memory in accordance with the invention employs current-drive mode in operation. The first phase change layer 11 and the second phase change layer 12 are heated by imposing different currents on the first electrode 41 and the second electrode 42. Then the first phase change layer 11 and the second phase change layer 12 generate zero, one, or two amorphous volumes because of the material characteristics. In the invention, two amorphous volumes are referred to as the second state; one amorphous volume is referred as the third state and fourth state; zero amorphous volumes is referred to as the first state. Schematic diagrams of all the states are illustrated in FIG. 4A˜FIG. 4D. The phase change layer with amorphous volumes has the highest resistance. Therefore, the series resistance of the second state is highest, the second highest is the third state, the third highest is the fourth state and the first state's resistance is lowest. Four resistance levels correspond to four memory states, thereby achieving four memory states.

According to the principle of the invention, the physical parameters of the materials of the first phase change layer 11 and the second phase change layer 12 are estimated as in TABLE I, in which the first material is applied for the first phase change layer 11, while the second material is applied for the second phase layer 12, or vice versa.

TABLE I

| | FIRST | SECOND |
|---|---|---|
| | MATERIAL | MATERIAL |
| Crystallization resistance (Ω-cm) | 5 × 10⁻³ | 1 × 10⁻² |
| Amorphization resistance (Ω-cm) | 50 | 100 |
| Crystallization Temperature (° C.) | 190 | 150 |
| Melting point (° C.) | 570 | 610 |
| Specific heat (J/cm³K) | ˜1.0 | ˜1.0 |
| Thermo-conductivity coefficient (W/cmK) | 0.17 | 0.14 |

The materials listed hereinafter are exemplary and explanatory and are not intended to limit the materials for the phase change memory of the invention. Therefore, people skilled in the related art may obtain a phase change memory with four memory states through selecting other proper materials.

The amorphous volumes of the first material and the second material are supposed to be the same. The ratio of the thickness and the crystallized area is 1:9. The size of the heating electrodes is the same. The total resistance for each state is estimated as follows.

<First State>

The first phase change layer and the second phase change layer crystallize.
R1=(5×10−3)×10+[(1×10'2)×10˜0.15

<Second State>

The first phase change layer crystallizes, and the second phase change layer amorphizes.
R2=[50×1+(5×10−3)−9]+[(1×10−2)×10]˜50

<Third State>

The first phase change layer amorphizes, and the second phase change layer crystallizes.
R3=[(5×10−3)×10]+[100×1+(1×10−2)×9]˜100

<Fourth State>

The first phase change layer and the second phase change layer amorphize.
R4=[50×1+(5×10−3)×9]+[100×1+(1×10−2)×9]˜150

From the estimation, the total resistance is determined by the resistance of the amorphized area. Therefore, the memory state may be determined by reading the voltage of the memory.

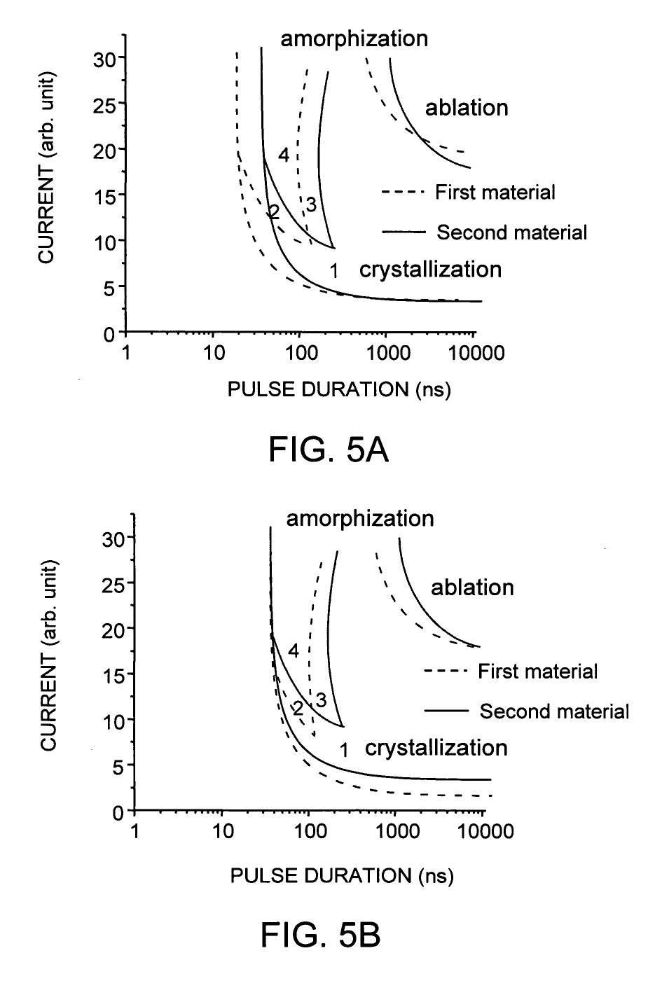

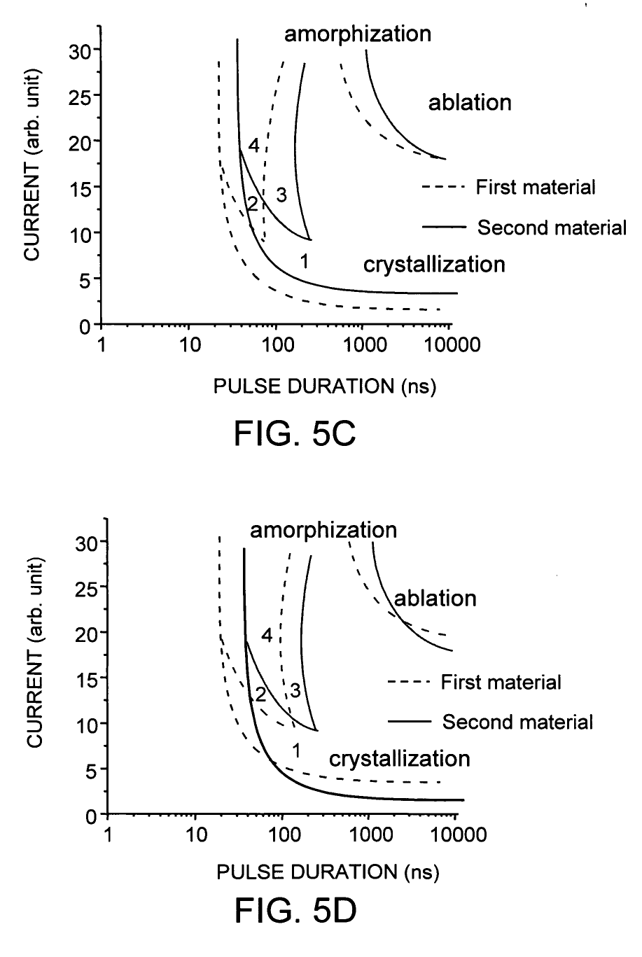

Refer to FIGS. 5A to 5D for the characteristic curves of the conditions listed above. Areas I, II, III, and IV in the figures may be obtained by selecting proper materials or adjusting the size of the structures.

A current pulse test of single phase change cell is performed for the first material and the second material. The conditions for amorphization and crystallization may be obtained by modulating current (I) and time (t). A crystallized cell is employed for the amorphization test, while a written cell is employed for the crystallization test. The test results are shown in the I-t diagram, which has an amorphization area, a crystallization area, and an ablation area. The amorphization area and the crystallization area may be adjusted to not totally overlap by adjusting the structural parameters of the memory cell. Thus, there are multiple correspondent relationships according to different phase change materials. For example, higher crystallization temperature corresponds to a higher bottom edge of the crystallization area; a higher melting point corresponds to a higher bottom edge of the amorphization area; and faster crystallization speed corresponds to a front edge of the crystallization area and the amorphization area.

When two memories are connected in series and the current pulse (I, t) falls in the overlapping amorphization area (AREA IV), each phase change layer has an amorphous volume. When the current pulse (V, t) falls in the amorphization area of the first material and does not overlap with the amorphization area of the second material (AREA III), the first phase change layer has an amorphous volume while the second phase change layer does not act. When the current pulse (V, t) falls in the amorphization area of the second material and does not overlap with the amorphization area of the first material (AREA II), only the second phase change layer generates an amorphous volume, while the first phase change layer melts, cools down smoothly and then crystallizes. When the current pulse (V, t) falls in the overlapping crystallization area (AREA I), the two phase change layers crystallize no matter which state they have.

Different first materials and second materials are selected for testing by adjusting structural parameter properly; the obtained results are illustrated in FIGS. 5A˜5D. From the results illustrated in these figures, four memory states formed by two phase change layers are obtained.

According to the principle of the invention, two methods may be adopted for the operation of the phase change memory when transferring different memory states.

The two methods are referred as zero mode and direct overwrite mode hereinafter. The memory states (second, third and fourth sate) are returned to zero, i.e., the first state (the first phase change layer and the second phase change layer crystallize) for the operation of the zero mode, and are transferred to another memory state. The operation is given as follows.

A two-staged operation is used in the zero mode operation. For any state transformation, a first pulse is imposed on the first phase change layer and the second phase change layer such that the first phase change layer and the second phase change layer crystallize to return to the first state. Then a second pulse is imposed to change the crystallization of the first phase change layer and the second phase change layer according to the memory condition.

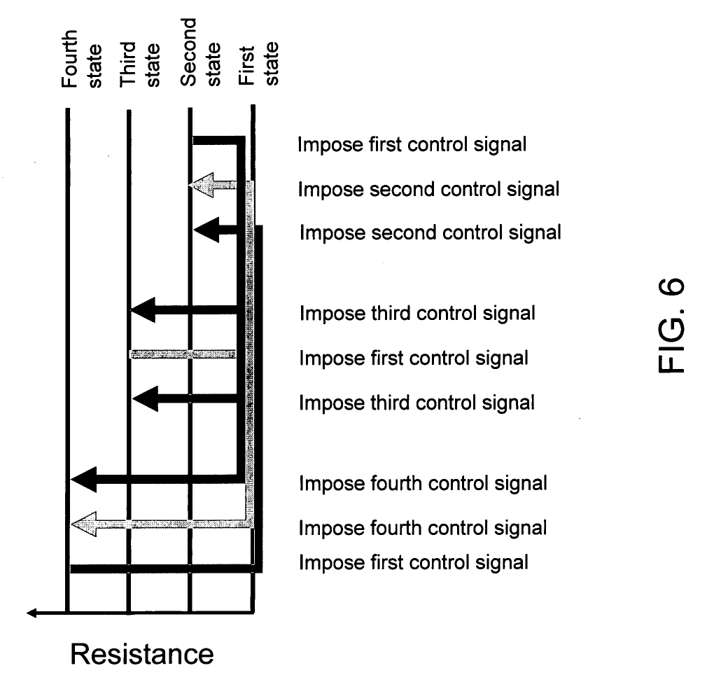

Detailed operations are described as follows, referring to FIG. 6.

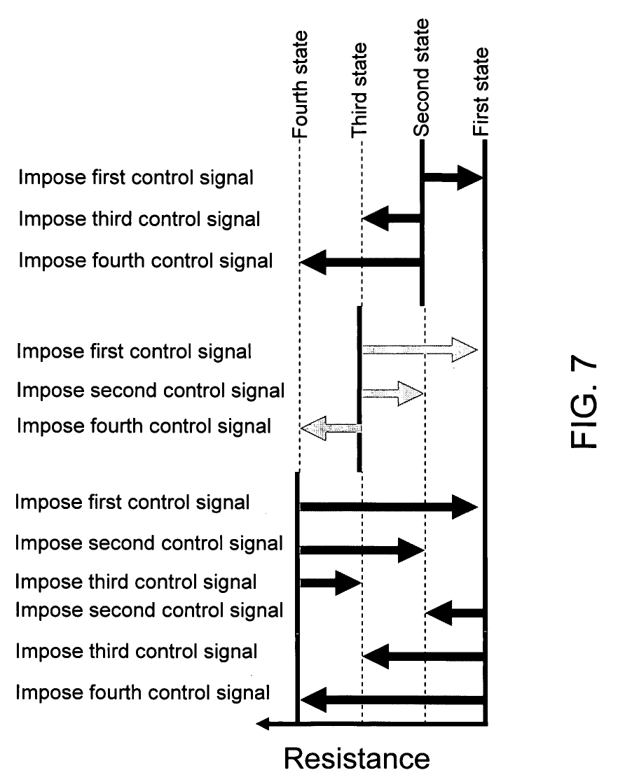

The Y-axis in FIG. 7 refers to read out voltages, in which the highest represents the first state, the second state, the third state, and the fourth state in turn. The arrow direction represents the control signals for different memory states. According to the principle of the invention, energy for each memory state is different. Therefore, four control signals are needed according to the resistance of each state. The signals are referred to as the first control signal, the second control signal, the third control signal, and the fourth control signal, which correspond to the first state, the second state, the third state, and the fourth state respectively.

The control signals corresponding to the state transformation of the phase change layers are listed in TABLE II.

TABLE II

| | | first phase | second phase |
|---|---|---|---|
| control signal | state | change layer | change layer |
| first control signal | first | crystallization | crystallization |
| second control signal | second | amorphization | crystallization |
| third control signal | third | crystallization | amorphization |
| fourth control signal | fourth | amorphization | amorphization |

When imposing the first control signal, the first phase change layer and the second phase change layer turn to a crystallization state (first state). When imposing the second control signal, the layers turn to the second state. When imposing the third control signal, the layers turn to the third state. When imposing the fourth control signal, the layers turn to the fourth state.

As illustrated in FIG. 6, when transforming to the second state from the third state, the first control signal is imposed in the beginning such that the cell turns to the first state, and then the second control signal is imposed such the cell turns to the second state. In another embodiment, when transforming to the second state from the fourth state, the first control signal is imposed in the beginning such that the cell turns to the first state, and then the fourth control signal is imposed such the cell turns to the fourth state. Accordingly, in zero mode operation, two signals are needed to change the memory state. The first pulse is imposed to return the state to zero, and the second pulse is imposed such that the cell turns to the desired state. The pulses or control signals hereinafter are preferably voltage signals.

According to the principle of the invention, the control signals for the zero mode operation are fewer. Operation is easier, and does not have the problem of incomplete crystallization of the amorphization volume.

In another embodiment, the method is direct overwrite mode. The aforementioned zero operation is not necessary for the direct overwrite mode during state transformation. Similarly, four control signals are needed, which are listed in TABLE III.

TABLE III

| | | first phase | second phase |
|---|---|---|---|
| Control signal | state | change layer | change layer |
| first control signal | first | crystallization | crystallization |
| second control signal | second | amorphization | crystallization |
| third control signal | third | crystallization | amorphization |
| fourth control signal | fourth | amorphization | amorphization |

When imposing the first control signal, the first phase change layer and the second phase change layer turn to a crystallization state (first state). When imposing the second control signal, the layers turn to the second state. When imposing the third control signal, the layers turn to the third state. When imposing the fourth control signal, the layers turn to the fourth state.

As illustrated in FIG. 7, when transforming to the second state from the third state, only the second control signal is imposed. In another embodiment, when transforming to the fourth state from the second state, only the fourth control signal is imposed. Therefore, in direct overwrite mode, only one pulse is necessary for state transformation. The pulses or control signals hereinafter are preferably voltage signals.

The direct overwrite mode has the advantage of short transformation time, and the original memory state does not need to be detected first before transformation.

According to the aspects and principles of the invention, the multilevel memory cell is configured by two independent single phase change cells connected in series, which use the same drive current for writing and reading different resistance levels (read voltages).

The two independent phase change cells are configured to obtain two current-pulse (I-t) diagrams for state transformation operations in zero mode or direct overwrite mode.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A phase change memory comprising:
a first phase change layer having a first characteristic curve of a current-time relationship, in which at least includes a crystallization state and an amorphous state; and
a second phase change layer having a second characteristic curve of a current-time relationship, in which at least includes a crystallization state and an amorphous state;
wherein the first and second characteristic curves cross with each other to form a first state, a second state, a third state, and a fourth state; in the first state, the first phase change layer and the second phase change layer are at crystallization state; in the second state, the first phase change layer is at amorphous state and the second phase change layer is at crystallization state; in the third state, the first phase change layer is at crystallization state and the second phase change layer is at amorphous state; in the fourth state, the first phase change layer and the second phase change layer are at amorphous state.

2. The memory of claim 1, wherein the materials of the first phase change layer and the second phase change layer are the same.

3. The memory of claim 1, wherein the materials of the first phase change layer and the second phase change layer are different.

4. A phase change memory comprising:
a first phase change layer;
a second phase change layer;
an intermediate layer formed between the first phase change layer and the second phase change layer;
a first electrode formed on another side of the first phase change layer; and
a second electrode formed on another side of the second phase change layer.

5. The memory of claim 4, wherein the materials of the first phase change layer and the second phase change layer are the same.

6. The memory of claim 4, wherein the materials of the first phase change layer and the second phase change layer are different.

7. The memory of claim 4, wherein the materials of the first electrode and the second electrode are the same.

8. The memory of claim 4, wherein the materials of the first electrode and the second electrode are different.

9. The memory of claim 4, wherein the touch area of the first electrode and the first phase change layer is the same as that of the second electrode and the second phase change layer.

10. The memory of claim 4, wherein the touch area of the first electrode and the first phase change layer is different from that of the second electrode and the second phase change layer.

11. The memory of claim 4 further comprises a first functional layer formed between the first electrode and the first phase change layer.

12. The memory of claim 11, wherein the first functional layer is one or any combination of a heating layer for increasing heating efficiency, a nucleation accelerating layer for accelerating crystallization speed of the first phase change layer, a diffusion stop layer for preventing diffusion between the first phase change layer and the first electrode.

13. The memory of claim 4 further comprises a second functional layer formed between the second electrode and the second phase change layer.

14. The memory of claim 11, wherein the second functional layer is one or any combination of a heating layer for increasing heating efficiency, a nucleation accelerating layer for accelerating crystallization speed of the second phase change layer, a diffusion stop layer for preventing diffusion between the second phase change layer and the second electrode.

15. A manufacture method for fabricating a phase change memory comprising:
providing a substrate, in which a metal contact is formed;
forming a first electrode on the substrate;
forming a first phase change layer, and forming an intermediate layer and a second phase change layer on the first electrode sequentially; and
forming a second electrode on the second phase change layer.

16. The manufacture method of claim 15 further comprises a step of forming a first functional layer on the first electrode.

17. The manufacture method of claim 15 further comprises a step of forming a second functional layer on the second phase change layer.

18. The manufacture method of claim 15, wherein a first functional layer is formed before forming the first electrode; wherein the first functional layer is one or any combination of a heating layer for increasing heating efficiency, a nucleation accelerating layer for accelerating crystallization speed of the first phase change layer, diffusion stop layer for preventing diffusion between the first phase change layer and the first electrode.

19. The manufacture method of claim 15, wherein a second functional layer is formed before forming the second electrode; wherein the second functional layer is one or any combination of a heating layer for increasing heating efficiency, a nucleation accelerating layer for accelerating crystallization speed of the second phase change layer, diffusion stop layer for preventing diffusion between the second phase change layer and the second electrode.

20. The manufacture method of claim 15 further comprises a step of forming an oxide layer before forming the first electrode.

21. The manufacture method of claim 15 further comprises a step of forming an oxide layer before forming the second electrode.

22. A state transformation method for a phase change memory having at least a first phase change layer and a second phase change layer, each of the layers has at least a crystallization state and an amorphous state such that four memory states are formed, comprising:
imposing a first pulse to make the first phase change layer and the second change layer crystallize, wherein the first pulse is a voltage signal; and
imposing a second pulse to change the crystallization state of the first phase change layer and the second change layer crystallize, wherein the second pulse is a voltage signal.

23. A state transformation method for a phase change memory having at least a first phase change layer and a second phase change layer, each of the layers has at least a crystallization state and an amorphous state such that four memory states are formed, comprising:
imposing a pulse to change the crystallization state of the first phase change layer and the second change layer crystallize, wherein the pulse is a voltage signal.
